(19) United States
(12) Patent Application Publication
(10) Pub. No.: US 2018/0123038 A1
(43) Pub. Date: May 3, 2018

(54) APPARATUS AND METHOD FOR FABRICATING A HIGH DENSITY MEMORY ARRAY

(71) Applicant: Intel Corporation, Santa Clara, CA (US)

(72) Inventors: Kevin J. LEE, Beaverton, OR (US); Yih WANG, Portland, OR (US); Elliot N. TAN, Portland, OR (US)

(73) Assignee: Intel Corporation, Santa Clara, CA (US)

(21) Appl. No.: 15/567,575

(22) PCT Filed: May 18, 2015
(86) PCT No.: PCT/US15/31440

§ 371 Date: Oct. 18, 2017

(51) Int. Cl. H01L 45/00; H01L 27/108; H01L 27/22; H01L 43/08; H01L 43/12; H01L 27/24

(52) U.S. Cl. CPC H01L 45/1683; H01L 27/10826; H01L 27/10814; H01L 27/10879; H01L 27/10855; H01L 45/08; H01L 43/08; H01L 43/12; H01L 27/2436; H01L 27/2463; H01L 45/06; H01L 27/228

(57) ABSTRACT

Described is an apparatus which comprises: non-orthogonal transistor fins which are non-orthogonal to transistor gates; diffusion contacts with non-right angled sides, the diffusion contacts coupled to the non-orthogonal transistor fins; first vias; and at least one memory element coupled to at least one of the diffusion contacts through at least one of the first vias.

### BACKGROUND

Computers and other electronic devices commonly use Dynamic Random-Access Memory (DRAM) integrated circuits for the temporary storage of programs and/or data. In DRAM, each bit of data is stored in a separate storage capacitor within the integrated circuit. The storage capacitor can be in either of two states: charged or discharged. These two states represent the two values of a bit, commonly referred to as ‘0’ and ‘1’. A sensing circuitry is used to determine the state of charge of the storage capacitor (i.e., whether the storage capacitor is charged or discharged). The DRAM cell is designed such that the overall capacitance and capacitance variation of the storage capacitor are minimized while the resistance of the interconnect that connects access transistors to the storage capacitors is of secondary importance.

However, going forward DRAM faces severe scaling issues. As the size of the storage capacitors continues to shrink, less and less charge can be stored in the storage capacitors. In the not too distant future the storage capacitors are expected to be so small that the sensing circuitry may not be able to accurately determine the state of the storage capacitor (e.g. charged vs. discharged). For this reason other types of memory devices are being actively explored in the electronics industry.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a top view of a memory layout with self-aligned source lines, according so some embodiments of the disclosure.

FIG. 2 illustrates a schematic of a pair of memory bit-cells coupled to the self-aligned source lines, according to some embodiments of the disclosure.

FIGS. 3A-W illustrate cross-sections of the memory layout of FIG. 1, after various fabrication processes, according to some embodiments of the disclosure.

FIG. 4 illustrates a smart device or a computer system or a SoC (System-on-Chip) having memory with self-aligned source lines, according to some embodiments.

### DETAILED DESCRIPTION

One of the main contenders to the DRAM is resistive memory. One type of resistive memory is Spin Transfer Torque Magnetic Random Access Memory (STT-MRAM). In STT-MRAM, each bit of data is stored in a separate magnetic tunnel junction (MTJ). MTJ is a magnetic element that is comprised of two magnetic layers separated by a thin insulating layer. One of the magnetic layers is called the reference layer (RL) or the pinned magnetic layer, and it provides a stable reference magnetic orientation. The bit is stored in the second magnetic layer which is called the free layer (FL), and the orientation of the magnetic moment of the free layer can be either in one of two states—parallel to the reference layer or anti-parallel to the reference layer.

Because of the tunneling magneto-resistance (TMR) effect, the electrical resistance of the anti-parallel state is significantly higher compared to the parallel state. To write information in a STT-MRAM device, the spin transfer torque effect is used to switch the free layer from the parallel to anti-parallel state and vice versa. The passing of current through the MTJ produces spin polarized current, which results in a torque being applied to the magnetization of the free layer. When the spin polarized current is sufficiently strong, enough torque is applied to the free layer to cause its magnetic orientation to change, thus allowing for bits to be written.

To read the stored bit, the sensing circuitry measures the resistance of the MTJ. Since the sensing circuitry needs to determine whether the MTJ is in the low resistance (e.g. parallel) state or in the high resistance state (e.g. anti-parallel) with acceptable signal-to-noise, the STT-MRAM cell needs to be designed such that the overall electrical resistance and resistance variation of the cell are minimized and the capacitance of the cell is of secondary importance. Note that these STT-MRAM cell design requirements are the opposite of that for the DRAM as described above. So, using prior art Dynamic Random Access Memory (DRAM) cell layouts does not result in optimal STT MRAM performance.

Some embodiments here describe an apparatus which comprises non-orthogonal transistor fins (or tilted transistor fins) and diffusion contacts with non-right angled sides (which are also described here as drain-side parallelogram-shaped diffusion contact and source-side parallelogram-shaped diffusion contact) coupled to the non-orthogonal transistor fins. In some embodiments, the apparatus further comprises first vias and at least one memory element coupled to at least one of the parallelogram-shaped diffusion contacts through at least one of the first vias. In some embodiments, at least one memory element is a capacitor or resistive memory device. In some embodiments, the capacitor is a MIM (Metal-Insulator-Metal) capacitor. In some embodiments, the resistive memory device is a MTJ based device. Various embodiments here are described with reference to a MTJ based device. However, the embodiments are applicable to other types of memory devices such as capacitive and resistive type memory devices. In some embodiments, the first vias are “MTJ pillar vias” (MPV's) that connect the bottom of the MTJs to the top of the drain-side parallelogram-shaped diffusion contacts, and wide source lines (SLs) that are self-aligned to the MPVs.

In some embodiments, a method for fabricating a high density memory array is described. In some embodiments, the method comprises: fabricating tilted transistor fins on a substrate and fabricating parallelogram-shaped diffusion contacts over the fabricated tilted transistor fins, where the parallelogram-shaped diffusion contacts are coupled to the tilted transistor fins. In some embodiments, the method comprises depositing an etch stop material over the parallelogram-shaped diffusion contacts, and depositing a dielectric layer over the etch stop material depositing a metallization hard mask layer over the dielectric layer. In some embodiments, the method further comprises applying a first photoresist over the metallization hard mask layer, where the first photoresist is patterned with holes for forming first vias (i.e., MPVs) for coupling at least one of the first vias to a memory element (e.g., capacitive or resistive memory element).

There are many technical effects of various embodiments. For example, self-aligning the SLs to the MPVs allow for the SLs to be as wide as possible which lowers the overall resistance of the interconnect layers between the access transistors and the MTJ devices. Lower SL resistance results in improved signal-to-noise for MTJ read operations. Lower SL resistance also lowers the transistor drive current requirements for MTJ write operations.

Because the SLs are self-aligned to the MPVs, the SLs can be considered to be “wrapped around” the MPVs in the final structure. One technical effect of self-aligning SLs to the MPVs is that it allows for the memory bit cell dimension, which is perpendicular to the source line direction, to be compressed which reduces the overall memory bit cell area. The method of fabricating the memory in accordance to several embodiments results in high density memory which is suitable for smaller form factors. Other technical effects will be evident from the description of various embodiments.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct electrical or magnetic connection between the things that are connected, without any intermediary devices. The term “coupled” means either a direct electrical or magnetic connection between the things that are connected or an indirect connection through one or more passive or active intermediary devices. The term “circuit” means one or more passive and/or active components that are arranged to cooperate with one another to provide a desired function. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level. The terms “substantially,” “close,” “approximately,” “near,” and “about,” generally refer to being within+/−20% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

For purposes of the embodiments, the transistors in various circuits and logic blocks described here are metal oxide semiconductor (MOS) transistors, which include drain, source, gate, and bulk terminals. The transistors also include Tri-Gate and FinFET transistors, Gate All Around Cylindrical Transistors, Tunneling FET (TFET), Square Wire, or Rectangular Ribbon Transistors or other devices implementing transistor functionality like carbon nano tubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.).

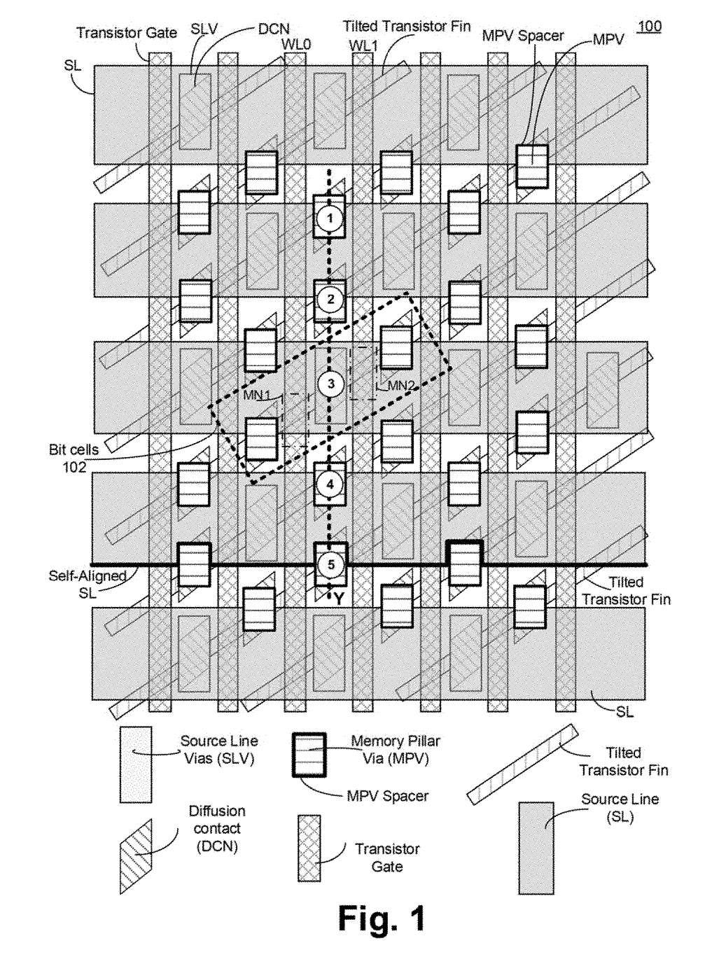

FIG. 1 illustrates top view 100 of a memory layout with self-aligned SLs, according to some embodiments of the disclosure. Top view 100 illustrates tilted transistor fins formed over a substrate (e.g., Sift) and parallelogram-shaped diffusion contacts (i.e., drain-side parallelogram-shaped diffusion contact and source-side parallelogram-shaped diffusion contact) coupled to the tilted transistor fin.

Here, the term “tilted” generally refers to a direction which is slanted relative to x, y, and/or z-axis (i.e., not orthogonal to x, y, and/or z planar axis). For example, the angle of tilt or slant may be between 0° and 90°. In some embodiments, the angle of tilt is in the range of 15° to 35°.

The term “tilted fin” or “non-orthogonal fin” generally refers to transistor fins that are slanted at an angle relative to the directions of the transistor gates, the source line interconnect, and/or the bit-line interconnect (also referred to as the bit-line). In some embodiments, the transistor fin is normal to the substrate surface (i.e., the transistor fin is not orthogonal to the substrate surface) and the transistor fin extends in the same plane as the source line interconnect (also referred to as the source line), but at an angle relative to the source line or the bit-line. Bit-lines and source lines generally extend in the same direction (i.e., are parallel). In some embodiments, depending on the memory technology, the angle of the tilt relative to the source line and bit-line, or only bit-lines.

For example, Phase Change Memory (PCM) cell and DRAM cell use bit-lines (i.e., source lines are not used). For these two memory applications, the tilted fin angle is relative to the bit-line. For STT-MRAM and RRAM (Resistive Random Access Memory), where bi-directional write is used for write operation, both bit-line and source-line are used. In such memories, the tilted fin angle is relative to the bit-line and source-line. In some embodiments, the tilted fin angle is 0 to 90 degrees relative to the source line and bit-line, or only bit-lines. In some embodiments, the tilted fin angle is 15 to 35 degrees relative to the source line and bit-line, or only bit-lines.

The term “parallelogram-shaped” generally refers to a shape which is substantially a parallelogram (i.e., a 4-sided flat shape with straight sides where opposite sides that are substantially parallel). For example, the opposite sides of the drain-side or source-side contact are parallel to each other or nearly parallel to each other. In some cases, it may be difficult to achieve a parallelogram-shape which has 100% parallel opposite sides because of process lithography limitations. The resulting shape in such cases is still within the scope of a parallelogram-shape even though the opposite sides are non-parallel. The term “parallelogram-shape” may also refer to a rhomboid in which adjacent sides are of unequal lengths and angles are non-right angled. The term “parallelogram-shape” may also refer to a rhombus with sides of equal length (i.e., equilateral).

While the embodiments are described with reference to drain-side and source-side contacts, other types of contacts may be used. For example, for BJTs, collector-side and emitter-side parallelogram-shaped contacts are used. The drain-side parallelogram-shaped diffusion contacts and source-side parallelogram-shaped diffusion contacts are on either sides of Transistor Gates.

In some embodiments, the Transistor Gates are coupled to word-lines (WL0, WL1, . . .). In some embodiments, the source-side parallelogram-shaped diffusion contacts are coupled to SLs through SL vias (SLVs). In some embodiments, the parallelogram-shaped diffusion contacts enable having wider SLs because space for overlay error is reduced. Wider SLs have lower resistance than narrower SLs. As such, the overall resistance variations are reduced which improves the performance of the memory. For example, by reducing the overall resistance of the SL, signal-to-noise for the memory element read operations is increased (i.e., improved) and current drive requirements for write operations to the memory element are lowered.

Generally, to protect from SL overlay on via or contacts, a space is required by process design rules between the SL edge and the via/contact. This space requirement increases the area of the memory array. The space requirement also pushes the memory design to have narrower SLs because wider SLs will increase the memory area, which is generally undesirable. Narrower SLs result in higher resistance which interferes with the read and write operations for the MTJ. Various embodiments reduce this space by making the rectangular or square diffusion contacts to parallelogram-shaped diffusion contacts. By reducing the space for the overlay error, memory density is increased because more bit-cells can be packed closer to one another than before. Also, the SL width can be increased to reduce the resistance of the SL.

In some embodiments, the drain-side parallelogram-shaped diffusion contacts are coupled to the memory elements through MPVs (also referred here to as the first vias). In some embodiments, the MPVs are covered with MPV spacers. In some embodiments, the SLs are self-aligned (as illustrated by the bold edge line of a SL). The SL edges align against part of the MPVs, and as such, memory bit-cell dimension is made perpendicular to the SL direction, in accordance to some embodiments. By making the memory bit-cell dimension to be perpendicular to the SL direction, overall area of the bit-cell is reduced which increases memory density. Because the SLs are self-aligned to the MPVs, the SLs are wrapped around the MPVs.

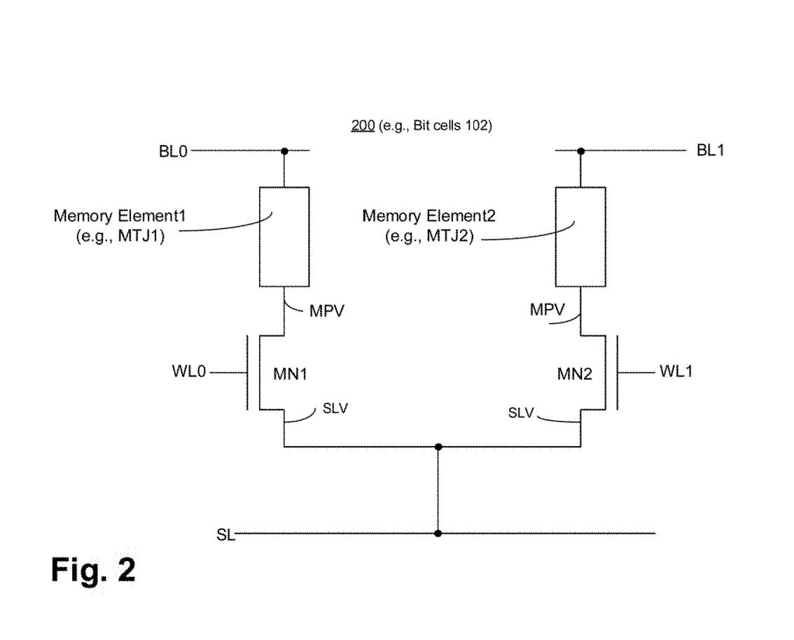

For sake of describing various embodiments, the memory elements are assumed to be MTJs (not shown in top view 100). However, other types of memory elements may be used. For example, the memory element may be a capacitor or resistive memory device. In some embodiments, the capacitor is a MIM capacitor. In some embodiments, the resistive memory device is a MTJ based device. In some embodiments, the resistive memory device is a phase change memory (PCM). Top view 100 also shows part of memory bit-cells (e.g., bit-cells 102). Bit-cells 102 include n-type transistors MN1 and MN2 with their source terminals coupled to a SL and their drain terminals for coupling to the MTJ devices. A schematic of the bit-cells 102 is described with reference to FIG. 2. While the embodiments are described with reference to n-type transistors, p-type transistors may also be used and a memory bit cell and be configured to operate with a p-type access transistors.

FIG. 2 illustrates a schematic 200 of a pair of memory bit-cells 102 coupled to self-aligned source lines, according so some embodiments of the disclosure. It is pointed out that those elements of FIG. 2 having the same reference numbers (or names) as the elements of any other figure can operate or function in any manner similar to that described, but are not limited to such.

In some embodiments, the first bit-cell includes n-type transistor MN1 having a gate terminal coupled to WL0, source terminal coupled to SL through SLV, and a drain terminal coupled to the bottom side of MTJ1 (i.e., Memory Element1) through MPV. In some embodiments, the drain terminal of transistor MN1 is coupled to the free layer of MTJ1. In some embodiments, the SL is a self-aligned SL. In some embodiments, the source and drain terminals of transistor MN1 are parallelogram shaped diffusion contacts.

In some embodiments, the second bit-cell includes n-type transistor MN2 having a gate terminal coupled to WL1, source terminal coupled to SL through SLV, and a drain terminal coupled to the bottom side of MTJ2 (i.e., Memory Element2) through MPV. In some embodiments, the drain terminal of transistor MN2 is coupled to the free layer of MTJ2. In some embodiments, the source and drain terminals of transistor MN2 are parallelogram shaped diffusion contacts. In some embodiments, the top sides of MTJ1 and MTJ2 are coupled to bit-lines (BLs). For example, MTJ1 is coupled to BL0 and MTJ2 is coupled to BL1.

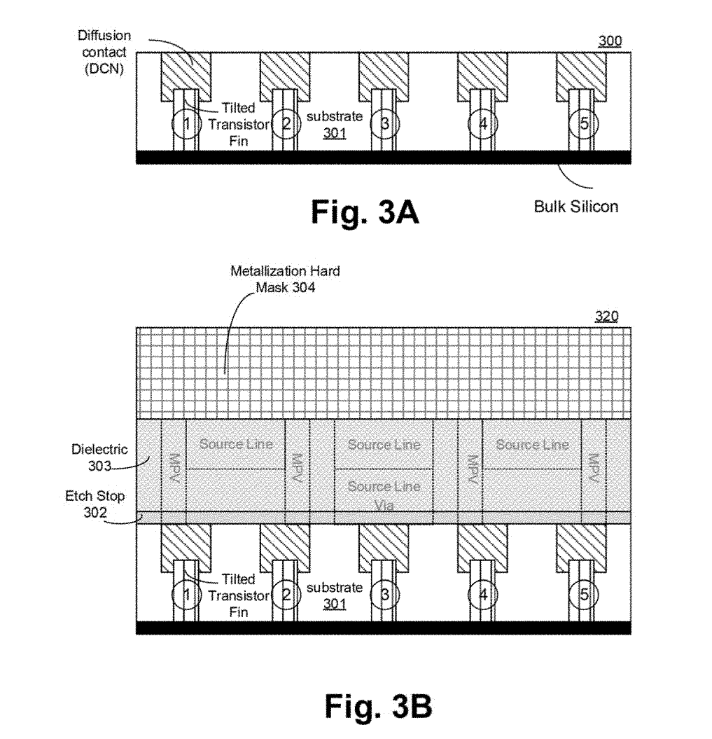

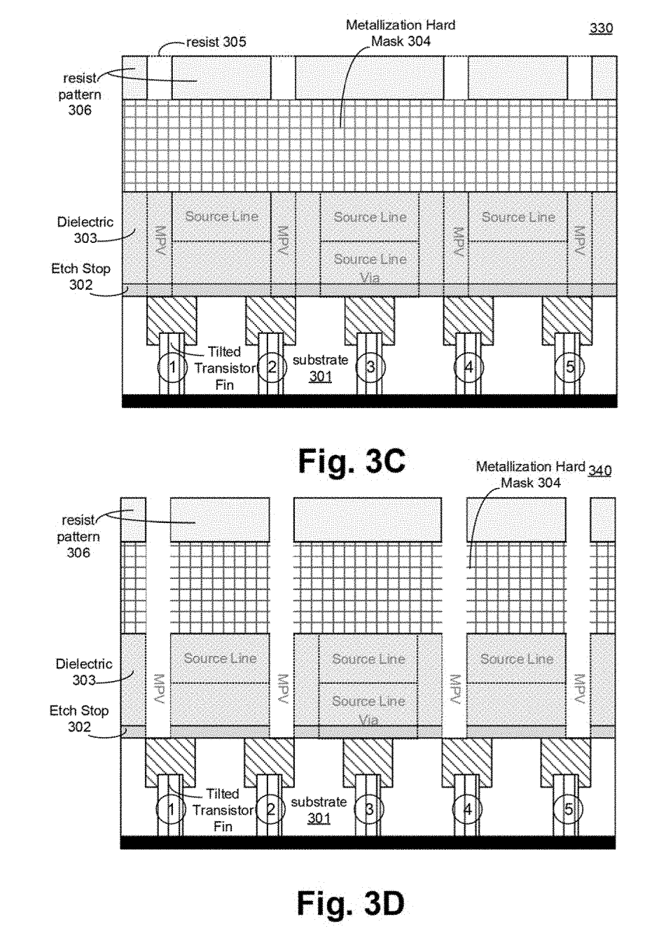

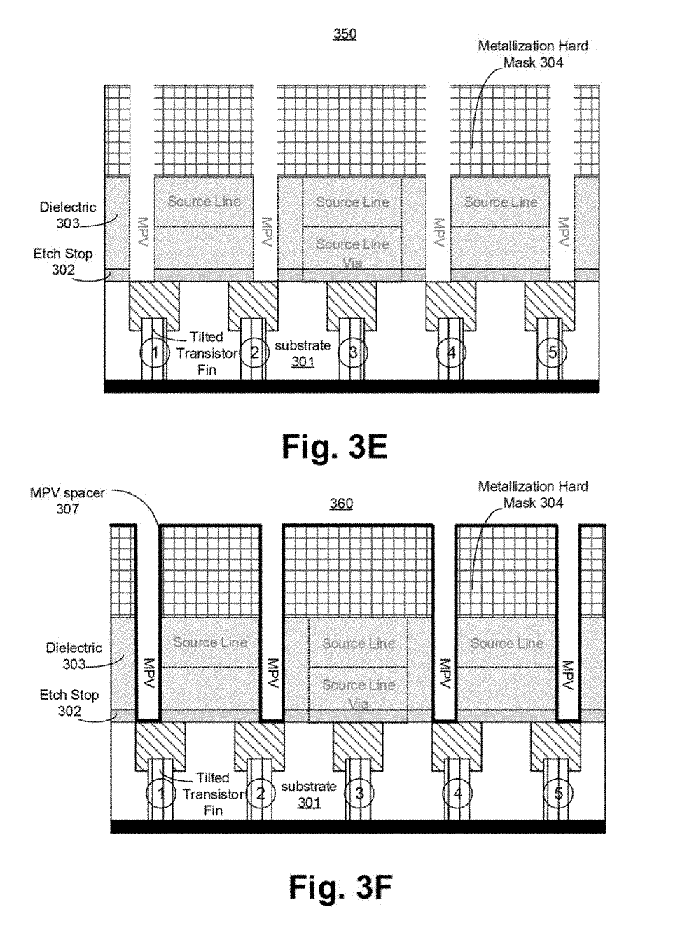

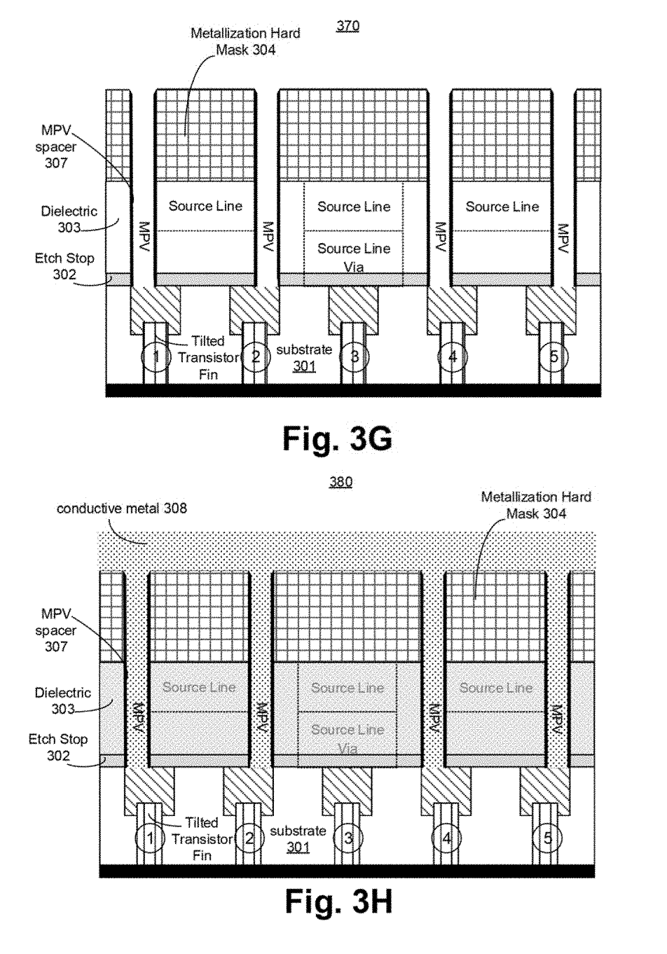

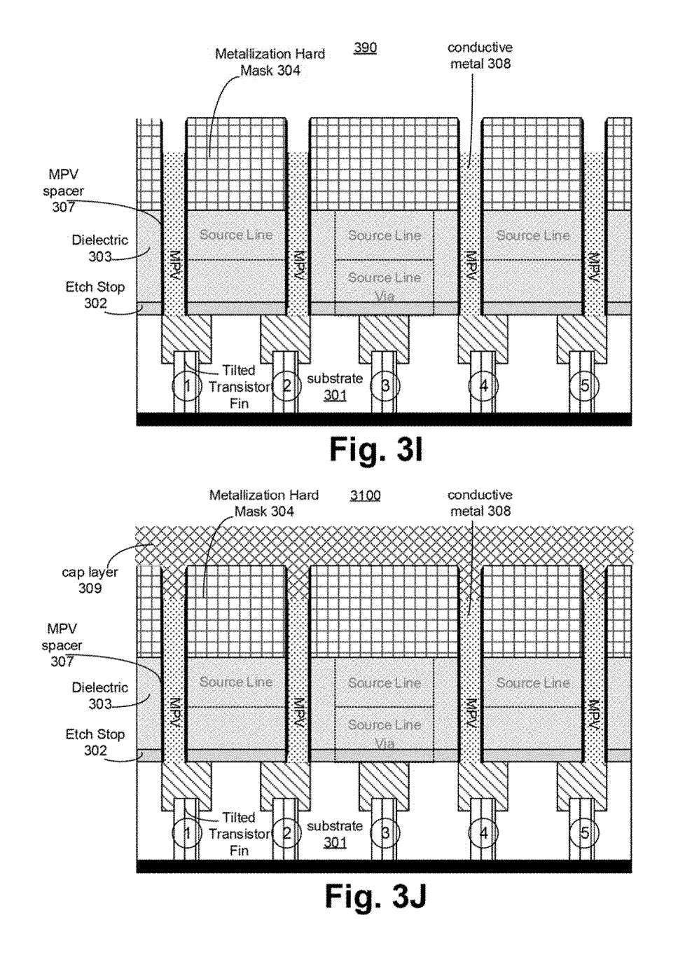

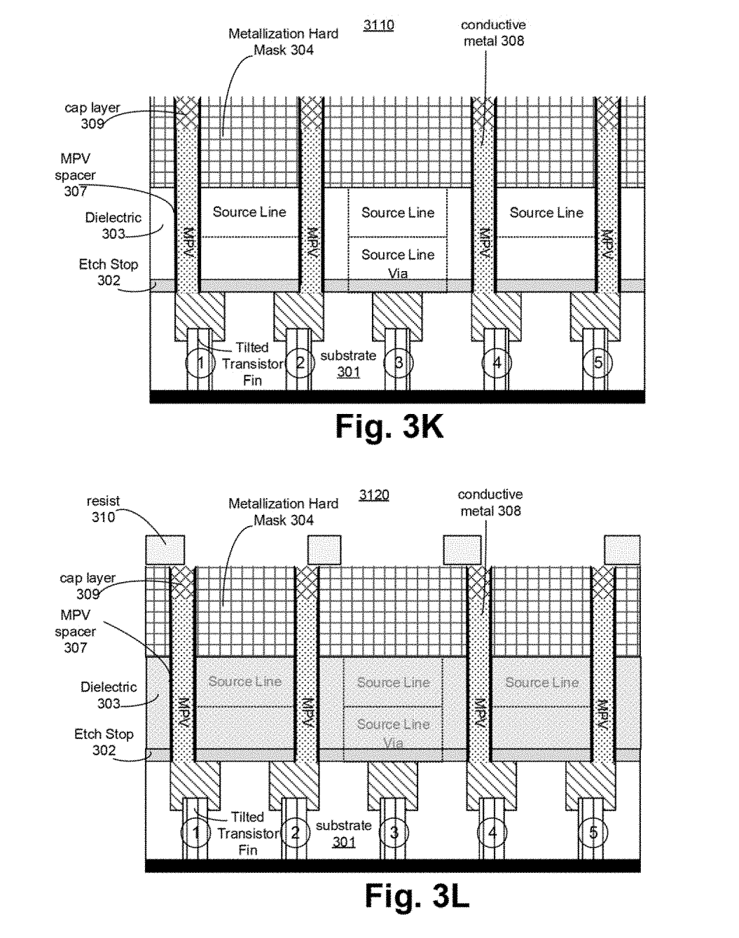

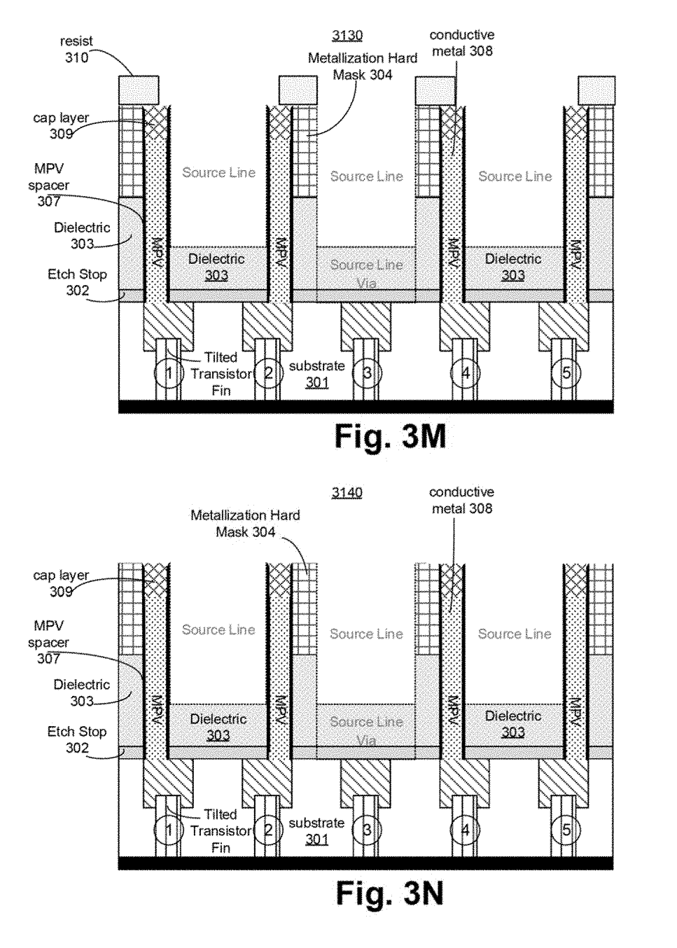

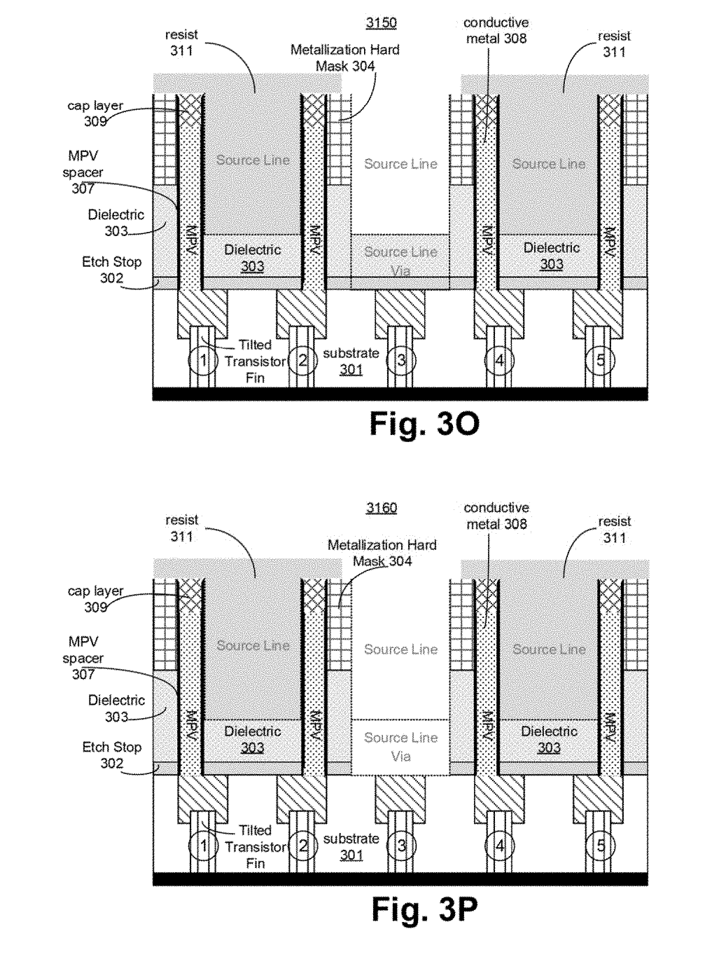

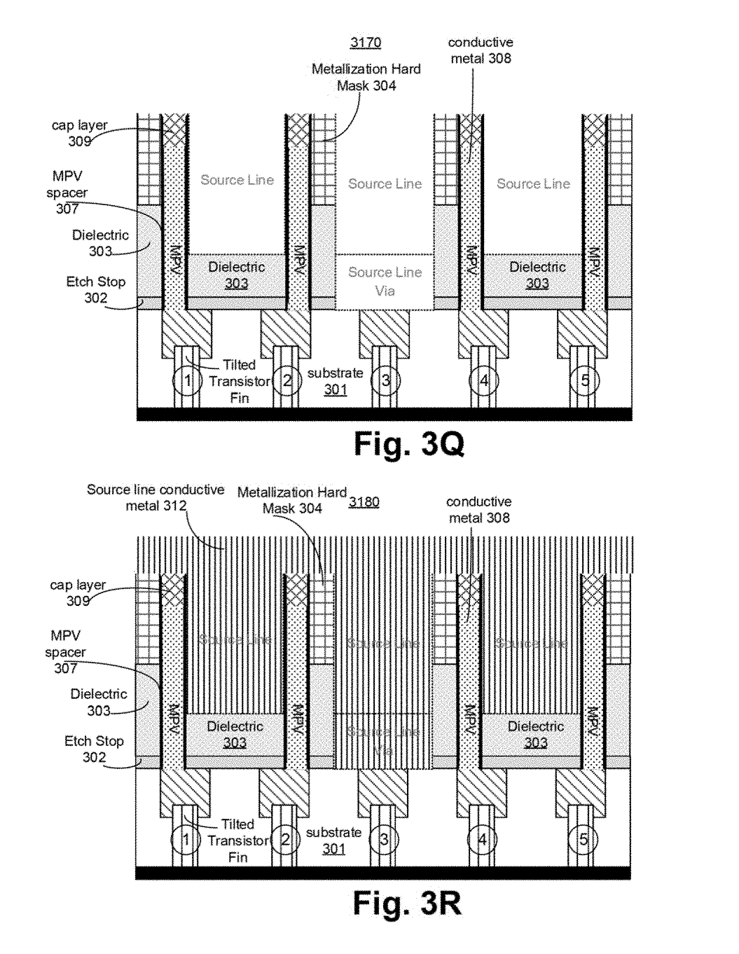

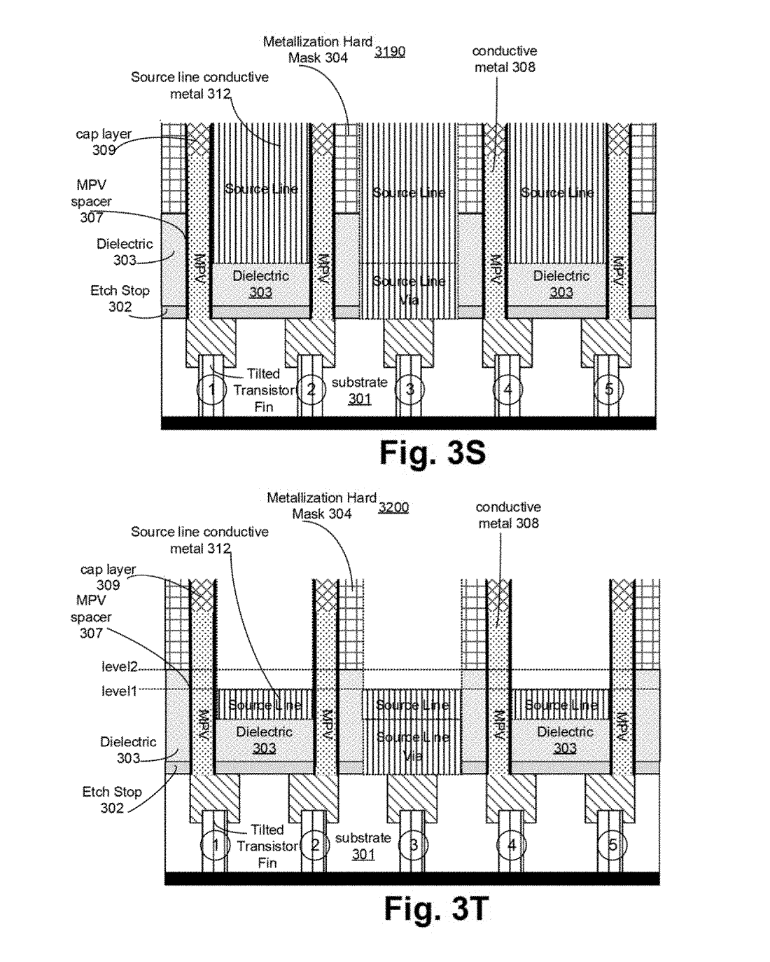

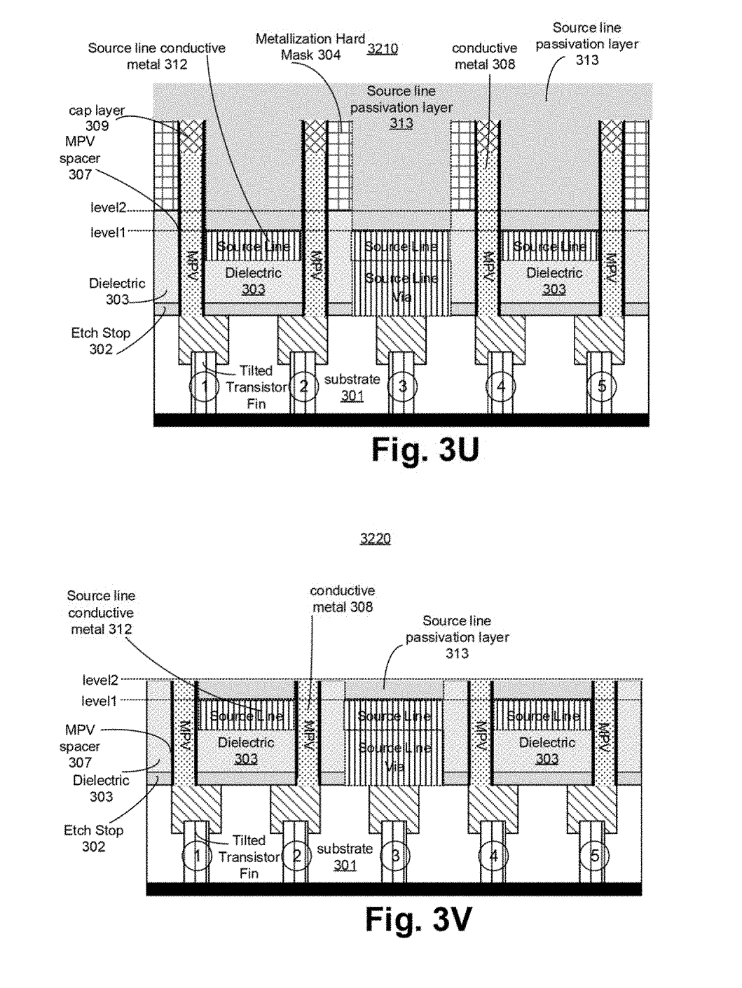

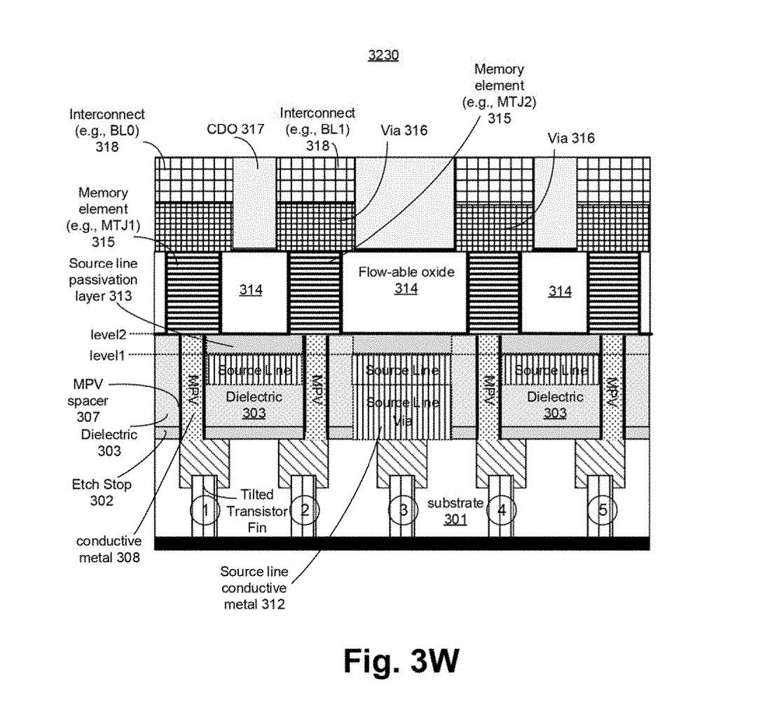

FIGS. 3A-W illustrate cross-sections 300-3230 of the memory layout of FIG. 1, after various fabrication processes, according to some embodiments of the disclosure. It is pointed out that those elements of FIGS. 3A-W having the same reference numbers (or names) as the elements of any other figure can operate or function in any manner similar to that described, but are not limited to such. Here, the cross-sections are for the dotted line ‘Y’ of FIG. 1 having five tilted transistor fins numbered as such.

FIG. 3A illustrates cross-section 300 of memory layout 100 having the five tilted transistors—1 through 5—formed in a substrate 301. The tilted transistor fins are coupled to parallelogram shaped diffusion contacts (i.e., source and drain contacts) also referred to here as DCN. Methods for fabricating tilted transistors is well known in the art. Method for fabricating parallelogram shaped diffusion contacts are also well known in the art. However, using parallelogram shaped diffusion contacts with tilted transistors in the context of forming capacitive or resistive memory, as described with reference to various embodiments, are novel.

FIG. 3B illustrates cross-section 320 showing an Etch Stop layer 302, Dielectric 302, and Metallization Hard Mask 304, according to some embodiments. In some embodiments, after the parallelogram diffusion contacts are fabricated, an Etch Stop material/layer 302 is deposited onto the wafer surface, followed by deposition of Dielectric layer 303 and a Metallization Hard Mask layer 304. The dotted regions in Dielectric layer 303 are meant to illustrate the future locations of Source Line, Source Line Via (SLV) and MPV.

In some embodiments, Etch Stop material/layer 302 may be at least one or more of: silicon nitride, silicon carbide, or silicon oxynitride. In some embodiments, Dielectric layer 303 may be at least one or more of a silicon dioxide, silicon nitride, fluorinated silicon oxide (SiOF), borophosphosilicate glass (BPSG), or a low k dielectric (e.g., k of less than three) such as carbon-doped oxide (CDO). In some embodiments, Metallization Hard Mask layer 304 may include one or more of silicon nitride, titanium nitride, tantalum nitride, titanium dioxide, or doped or undoped polysilicon, or a combination of these films.

FIG. 3C illustrates cross-section 330 showing application of photoresist layer 305 over Metallization Hard Mask layer 304, in accordance to some embodiments. In some embodiments, photoresist layer 305 is patterned as resist pattern 306 such that holes are formed in photoresist layer 305 where MPVs are desired. The photoresist layer 305 may include not only of photoresist material, but may also include other patterning materials such as anti-reflective coatings (ARCs) and gap-fill and planarizing materials that are applied using methods and techniques that are well-known in the art.

FIG. 3D illustrates cross-section 340 showing etching of Metallization Hard Mask layer 304, Dielectric layer 303, and Etch Stop Layer 302 where MPV holes are desired to be fabricated, in accordance with some embodiments. In some embodiments, Anisotropic dry etch processes are used to transfer resist pattern 306 in the Metallization Hard Mask layer 304 and then into Dielectric layer 303 and Etch Stop Layer 302.

FIG. 3E illustrates cross-section 350 showing removal of photoresist material 305, in accordance to some embodiments. In some embodiments, a plasma ash process is used to remove any remaining photoresist layer.

FIG. 3F illustrates cross-section 360 showing application of MPV spacer film 307. In some embodiments, after resist material 305 is removed, a thin layer of MPV spacer film 307 is applied on the wafer surface. In some embodiments, MPV spacer film 307 is made from one or more of silicon nitride or carbon-doped silicon nitride.

FIG. 3G illustrates cross-section 370 showing an application of an etch process for removing MPV spacer film 307 from the horizontal surfaces of the wafer, in accordance with some embodiments. In some embodiments, an anisotropic dry etch process is used to remove MPV spacer film 307 from all horizontal surfaces of the wafer while leaving the MPV spacer film 307 on the vertical sidewalls.

FIG. 3H illustrates cross-section 380 showing an application of conductive metal 308 on the wafer surface after MPV spacer film 307 is removed from the horizontal surfaces of the wafer, in accordance to some embodiments. In some embodiments, conductive metal 308 is one of copper, tungsten, or cobalt which is deposited onto the wafer surface, filling into the MPV gaps. In some embodiments, various barrier or adhesion films may be present at the interface between conductive metal 308 and MPV spacer 307, such as titanium, tantalum, titanium nitride, tantalum nitride, ruthenium, titanium-zirconium nitride, cobalt, etc.

FIG. 3I illustrates cross-section 390 showing partial etching of conductive metal 308. In some embodiments, conductive metal 308 is etched up till the horizontal edge of Metallization Hard Mask 304. In some embodiments, conductive metal 308 in the MPV is etched back using wet or dry etch techniques. Any known suitable wet or dry etch technique may be used for the etch-back process. In some embodiments, conductive metal 308 in the MPV is etched back such that the top surface of the MPV is recessed below the top surface of Metallization Hard Mask 304.

FIG. 3J illustrates cross-section 3100 showing the application of cap layer 309, in accordance to some embodiments. In some embodiments, cap layer 309 (also referred to as the MPV cap layer) is deposited on the wafer after conductive metal 308 in the MPV is etched back. Any suitable material can be used for cap layer 309. For example, silicon nitride and silicon carbide may be used as materials for cap layer 309.

FIG. 3K illustrates cross-section 3110 showing the application of a planarization process after application of cap layer 309. In some embodiments, MPV cap layer 309 is planarized using a Chemical Mechanical Process (CMP). In some embodiments, CMP process is selective to the top surface of Metallization Hard Mask Layer 304 such that the MPV cap layer material remains on top of the MPV after the CMP process is completed.

FIG. 3L illustrates cross-section 3120 showing the application of photoresist which is pattered as resist 310, according to some embodiments. In some embodiments, after the photoresist is patterned as resist 310, there are openings in the photoresist layer where SLs are desired. The photoresist layer may comprise not only of photoresist material, but may also include other patterning materials such as ARCs and gap-fill and planarizing materials that are applied using methods and techniques that are well-known in the art.

FIG. 3M illustrates cross-section 3130 showing the application of dry etch process after photoresist with openings in the photoresist layer where SLs are desired is applied, according to some embodiments. In some embodiments, anisotropic dry etch processes is used to transfer the resist pattern 310 into the Metallization Hard Mask 304 and then into part of Dielectric layer 303. In some embodiments, the source line trenches are self-aligned to the edges of the MPVs because the source line etch process etches the Metallization Hard Mask 304 material(s) and underlying Dielectric layer 303 material but does not substantially affect the MPV cap 309 and MPV spacer 307 materials.

For this reason the photoresist does not need to cover up the MPV top and edges, and the source line pattern in Dielectric layer 303 is “self-aligned” to the MPV edge. One who is skilled in the art will recognize that one benefit of the “self-aligned” process is that there is no need to leave space between the source line and the MPV to allow for overlay error between the MPV's and the subsequent source line resist pattern, and hence the bit-cell size can be made smaller. One who is skilled in the art will also recognize that another benefit of the “self-aligned” process is that the photoresist can be patterned as a simple line/space grating pattern which is easier to do at the reduced dimensions in state of the art semiconductor fabrication processes.

FIG. 3N illustrates cross-section 3140 showing the removal of remaining resist layer 310 from the surface of the wafer, according to some embodiments. In some embodiments, resist layer 310 is removed using a plasma ash process.

FIG. 3O illustrates cross-section 3150 showing the application of photoresist 311 after it has been patterned, according to some embodiments. In some embodiments, after patterning the photoresist (as shown by resist 311) there are openings in the photoresist layer where the source line vias (SLVs) are desired. In some embodiments, photoresist layer 311 may include not only of photoresist material, but may also include other patterning materials such as ARCs and gap-fill and planarizing materials that are applied using methods and techniques that are well-known in the art.

FIG. 3P illustrates cross-section 3160 showing the etching of Dielectric layer 303 where the SLV is desired, according to some embodiments of the disclosure. In some embodiments, anisotropic dry etch processes is used to transfer resist pattern into Dielectric layer 303 and the Edge Stop layer 302.

FIG. 3Q illustrates cross-section 3170 showing the removal of resist 311, according to some embodiments. In some embodiments, after etching of Dielectric layer 303 where SLV is desired, resist layer 311 is removed. In some embodiments, a plasma ash process is used to remove resist layer 311.

FIG. 3R illustrates cross-section 3180 showing the application of conductive metal 312 (also referred to as the SL conductive metal) after resist 311 is removed, according to some embodiments. In some embodiments, conductive metal such as copper, tungsten, or cobalt is deposited onto the entire wafer surface, filling into the source line trenches and source line via openings. In some embodiments, various barrier or adhesion films may be present at the interface between conductive metal 312 and MPV spacer 307. In some embodiments, various barrier or adhesion films such as titanium, tantalum, titanium nitride, tantalum nitride, ruthenium, titanium-zirconium nitride, cobalt, etc. may be used.

FIG. 3S illustrates cross-section 3190 showing the removal of overburden of conductive metal 312, according to some embodiments. In some embodiments, the conductive metal overburden is removed using wet etch, dry etch, and/or CMP processes, stopping on the MPV Cap Layer 309 and Metallization Hard Mask 304.

FIG. 3T illustrates cross-section 3200 showing etching back of SL conductive metal 312 after removing of overburden of conductive metal 312, according to some embodiments. In some embodiments, SL conductive metal 312 is etched back using wet or dry etch techniques that are known in the art, such that its top surface (i.e., level1) is recessed below the top surface of Dielectric Layer 303 (i.e., level2).

FIG. 3U illustrates cross-section 3210 showing deposition of SL passivation film 313 after etching back of SL conductive metal 312, according to some embodiments of the disclosure. In some embodiments, SL passivation film 313 is deposited onto the wafer surface using CVD (Chemical Vapor Deposition) techniques that are known in the art. Suitable SL passivation materials for SL passivation film 313 include silicon nitride and silicon carbide. However, other types of material may be used.

FIG. 3V illustrates cross-section 3220 showing the removal of overburden of SL passivation film 313, MPV cap 309, and Metallization Hard Mask 304, according to some embodiments. In some embodiments, the top portions of the MPV metallization and MPV spacers 307 are removed using CMP and dry and/or wet etch processes, stopping on Dielectric material 303 at level2.

FIG. 3W illustrates cross-section 3230 of memory layout when the memory layout includes the MTJ device and BL interconnect, according to some embodiments. Note, FIG. 1 does not show the MTJ device and the BL interconnect so as not to obscure various embodiments. In some embodiments, MTJ devices 315 (e.g., MTJ1 and MTJ2) are then fabricated on top of the MPVs (i.e., conduction metal 308). In some embodiments, MTJ devices 315 are formed before oxide material 314 (e.g., flow-able oxide) is deposited.

For example, MTJ devices 315 are formed and then flow-able oxide is deposited to fill the spaces in between MTJ devices. In some embodiments, any suitable fabrication process may be used for fabricating the MTJ devices 315 over the MPVs. In some embodiments, vias 316 are formed on top of the MTJ devices 315 to connect the MTJ devices 314 to interconnect layers. In some embodiments, subsequent interconnect layer(s) 318 are fabricated on top of vias 316 to couple to MTJ devices 315. Here, the subsequent interconnect layers 318 are used as bit-lines (i.e., BL0 and BL1). In some embodiments, any suitable fabrication process may be used for fabricating interconnect layer 318. In some embodiments, space between vias 316 and interconnect layer 318 are filled with CDO 317.

In some embodiments, the fabrication processes illustrated by cross-sections in FIGS. 3A-3W are represented as flow-chart of a method for fabricating a high density memory.

In some embodiments, the method comprises fabricating tilted transistor fins on substrate 301 and fabricating parallelogram-shaped DCN over the fabricated tilted transistor fins, where the parallelogram-shaped DCNs are coupled to the tilted transistor fins. In some embodiments, the method comprises depositing an Etch Stop material 302 over the parallelogram-shaped DCNs. In some embodiments, the method comprises depositing Dielectric layer 303 over Etch Stop material 302. In some embodiments, the method comprises depositing Metallization Hard Mask layer 304 over Dielectric layer 303, and applying a first photoresist 305 over Metallization Hard Mask layer 304, where first photoresist 305 is patterned with holes for forming first vias (i.e., MPVs) for coupling to at least one of the first vias to a memory element (e.g., MTJ, PCM, MIM capacitor, etc.).

In some embodiments, the method comprises applying a first anisotropic dry etch process to transfer the photoresist pattern 306 of first photoresist 305 into Dielectric layer 303 and Etch Stop material 302 such that holes (for MPVs) are formed. In some embodiments, the method comprises removing the first photoresist 305/306, and applying a spacer film 307 (i.e., MPV spacer) for forming the first vias (i.e., MPVs) after first photoresist 305/306 is removed.

In some embodiments, the method comprises applying a second anisotropic etch process to remove spacer film 307 from the horizontal surfaces while leaving spacer film 307 on the vertical surfaces. In some embodiments, the method comprises depositing a first conductive metal 308 after applying the second anisotropic etch process such that the deposited first conductive metal 308 fills the first vias (i.e., MPVs).

In some embodiments, the method comprises etching back first conductive metal 308 partially from the first vias (i.e., MPVs). In some embodiments, the method comprises depositing a cap layer 309 over the etched back first conductive metal 308. In some embodiments, the method comprises polishing cap layer 309 such that cap layer 309 remains above the first vias. In some embodiments, the method comprises applying a third photoresist and patterning the third photoresist 310 for forming source lines. In some embodiments, the method further comprises applying a third anisotropic etch process to form source line trenches, the third anisotropic etch process to etch partially through dielectric layer 303. In some embodiments, the method comprises removing the third photoresist 310 after applying the third anisotropic etch process.

In some embodiments, the method comprises applying a fourth photoresist 311 with a pattern for forming a second via (i.e., SLV), and applying a fourth anisotropic etch process to etch the fourth photoresist 311 through Dielectric layer 303 and Etch Stop material 302 to just above at least one of the parallelogram-shaped DCNs. In some embodiments, the method comprises depositing a second conductive metal 312 such that the second via (i.e., SLV) and the source line trenches are filled with second conductive metal 312. In some embodiments, the method comprises removing the overburden of second conductive metal 312 such that the overburden is removed up to cap layer 309 and Metallization Hard Mask layer 304.

In some embodiments, the method comprises etching second conductive metal 312, in response to removing the overburden from the source line trenches such that the etching stops below a top surface of Dielectric Layer 303. In some embodiments, the method comprises depositing a source line passivation film 313 in response to etching second conductive metal 312. In some embodiments, the method comprises removing overburden of source line passivation film 313 and Metallization Hard Mask layer 304 such that the first via and the filled source line is exposed.

In some embodiments, the method comprises forming a memory element 315 such that one end of memory element 315 couples the first via. In some embodiments, the method comprises forming an interconnect 318 and coupling it to the filled source line.

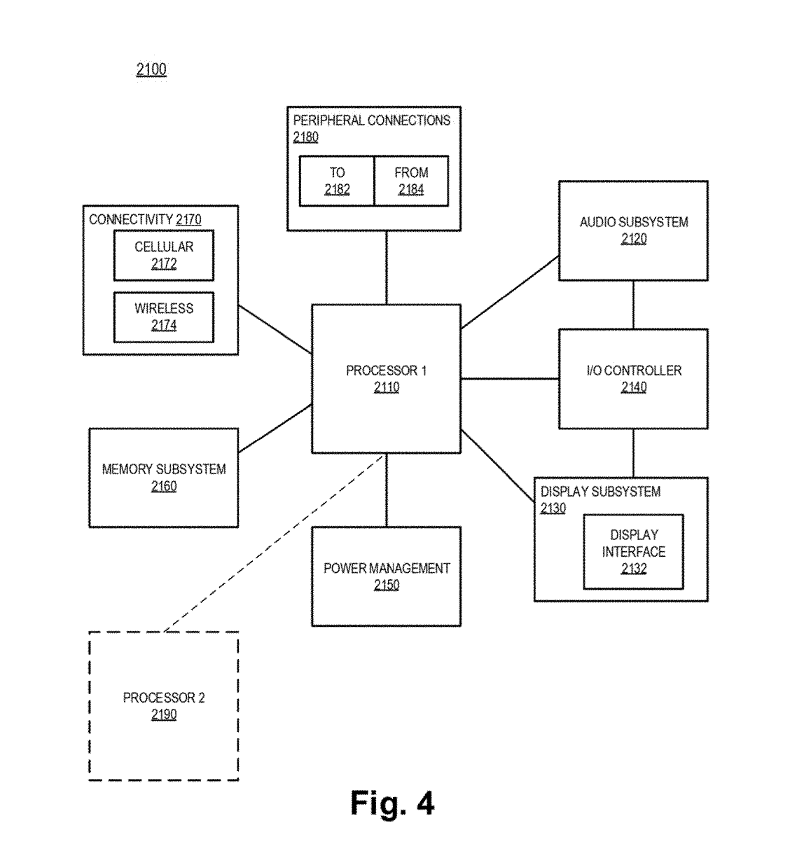

FIG. 4 illustrates a smart device or a computer system or a SoC (System-on-Chip) having memory with self-aligned source lines, according to some embodiments. It is pointed out that those elements of FIG. 4 having the same reference numbers (or names) as the elements of any other figure can operate or function in any manner similar to that described, but are not limited to such.

FIG. 4 illustrates a block diagram of an embodiment of a mobile device in which flat surface interface connectors could be used. In some embodiments, computing device 2100 represents a mobile computing device, such as a computing tablet, a mobile phone or smart-phone, a wireless-enabled e-reader, or other wireless mobile device. It will be understood that certain components are shown generally, and not all components of such a device are shown in computing device 2100.

In some embodiments, computing device 2100 includes a first processor 2110 with high density memory, according to some embodiments discussed. Other blocks of the computing device 2100 may also include the high density memory of some embodiments. The various embodiments of the present disclosure may also comprise a network interface within 2170 such as a wireless interface so that a system embodiment may be incorporated into a wireless device, for example, cell phone or personal digital assistant.

In one embodiment, processor 2110 (and/or processor 2190) can include one or more physical devices, such as microprocessors, application processors, microcontrollers, programmable logic devices, or other processing means.

The processing operations performed by processor 2110 include the execution of an operating platform or operating system on which applications and/or device functions are executed. The processing operations include operations related to I/O (input/output) with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, an apparatus is provided which comprises: non-orthogonal transistor fins which are non-orthogonal to transistor gates; diffusion contacts with non-right angled sides, the diffusion contacts coupled to the non-orthogonal transistor fins; first vias; and at least one memory element coupled to at least one of the diffusion contacts through at least one of the first vias. In some embodiments, the at least one of the diffusion contacts is a drain-side diffusion contact, and wherein at least another one of the diffusion contacts is a source-side diffusion contact.

In some embodiments, the apparatus comprises source lines which partially wrap around the first vias such that the source lines are self-aligned with respect to each other. In some embodiments, the apparatus comprises second vias, wherein at least one of the second vias couples at least one of the source lines to the source-side diffusion contact. In some embodiments, at least one of the first vias is coupled to a terminal of the at least one memory element and a section of the drain-side diffusion contact. In some embodiments, the non-orthogonal transistor fins are non-parallel to the source lines. In some embodiments, the diffusion contacts are rhomboids. In some embodiments, the diffusion contacts are rhombuses. In some embodiments, the memory element is one of a capacitor or resistive memory element. In some embodiments, the memory element is a resistive memory element which is at least one of: a magnetic tunneling junction; a capacitor; a phase change memory; or a resistive random access memory (RRAM) material. In some embodiments, the first via is a magnetic tunneling junction (MTJ) pillar via.

In another example, a system is provided which comprises: a processor; a memory coupled to the processor, the memory including an apparatus according to the apparatus described above; and a wireless interface for allowing the processor to communicate with another device.

In another example, a system is provided which comprises: means for processing; means for storing coupled to the means for processing, the means for storing including an apparatus according to the apparatus described above; and means for allowing the means for processing to communicate with another device.

In another example, a method is provided which comprises: fabricating non-orthogonal transistor fins on a substrate, the transistor fins being non-orthogonal relative to a plane of the substrate; fabricating diffusion contacts with non-right angled sides over the fabricated non-orthogonal transistor fins, wherein the diffusion contacts are coupled to the non-orthogonal transistor fins; depositing an etch stop material over the diffusion contacts; depositing a dielectric layer over the etch stop material; depositing a metallization hard mask layer over the dielectric layer; and applying a first photoresist over the metallization hard mask layer, wherein the first photoresist is patterned with holes for forming first vias for coupling the at least one of the first vias to a memory element.

In some embodiments, the memory element is at least one of: a magnetic tunneling junction; a phase change memory; a resistive random access memory (RRAM); or a capacitor. In some embodiments, the method comprises applying a first anisotropic dry etch to transfer the photoresist pattern of the first photoresist into the dielectric layer and etch stop material such that holes are formed to a top surface of at least one of the diffusion contacts. In some embodiments, the method removing the first photoresist; and applying a spacer film for forming the first vias after the first photoresist is removed.

In some embodiments, the method comprises: applying a second anisotropic etch process to remove the spacer film from horizontal surfaces while leaving the spacer film on vertical surfaces; and depositing a first conductive metal after applying the second anisotropic etch process such that the deposited first conductive metal fills the first vias. In some embodiments, the method comprises: etching back the first conductive metal partially from the first vias; depositing a cap layer over the etched back first conductive metal; and polishing the cap layer such that the cap layer remains above the first vias.

In some embodiments, the method comprises: applying a third photoresist and patterning the third photoresist for forming source lines; applying a third anisotropic etch process to form source line trenches, the third anisotropic etch process to etch partially through the dielectric layer; and removing the third photoresist after applying the third anisotropic etch process. In some embodiments, the method comprises: applying a fourth photoresist with a pattern for forming a second via; and applying a fourth anisotropic etch process to transfer the fourth photoresist pattern through the dielectric layer and the etch stop material to just above at least one of the diffusion contacts.

In some embodiments, the method comprises: depositing a second conductive metal such that the second via and the source line trenches are filled with the second conductive metal; and removing overburden of the second conductive metal such that the overburden is removed up to the cap layer and the metallization hard mask layer. In some embodiments, the method comprises: etching the second conductive metal, in response to removing the overburden from the source line trenches such that the etching stops below a top surface of the dielectric layer; depositing a source line passivation film in response to etching the second conductive metal; and removing overburden of the source line passivation film and metallization hard mask layer such that the first via and the filled source line is exposed. In some embodiments, the method comprises forming a memory element such that one end of the memory element couples the at least one of the first vias. In some embodiments, the method comprises forming an interconnect and coupling the interconnect to the filled source line.

In another example, a machine readable storage media is provided having machine executable instructions, that when executed, cause one or more processors to perform an operation according to the method described above.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-24. (canceled)

25. An apparatus comprising:
non-orthogonal transistor fins which are non-orthogonal to transistor gates;
diffusion contacts with non-right angled sides, the diffusion contacts coupled to the non-orthogonal transistor fins;
first vias; and
at least one memory element coupled to at least one of the diffusion contacts through at least one of the first vias.

26. The apparatus of claim 25, wherein the at least one of the diffusion contacts is a drain-side diffusion contact, and wherein at least another one of the diffusion contacts is a source-side diffusion contact.

27. The apparatus of claim 26 comprises source lines which partially wrap around the first vias such that the source lines are self-aligned with respect to each other.

28. The apparatus of claim 27 comprises second vias, wherein at least one of the second vias couples at least one of the source lines to the source-side diffusion contact.

29. The apparatus of claim 26, wherein at least one of the first vias is coupled to a terminal of the at least one memory element and a section of the drain-side diffusion contact.

30. The apparatus of claim 27, wherein the non-orthogonal transistor fins are non-parallel to the source lines.

31. The apparatus of claim 25, wherein the diffusion contacts are one of rhomboids or rhombuses.

32. The apparatus of claim 25, wherein the memory element is a resistive memory element which is at least one of:
a magnetic tunneling junction;
a capacitor;
a phase change memory; or
a resistive random access memory (RRAM) material.

33. The apparatus of claim 25, wherein the first via is a magnetic tunneling junction (MTJ) pillar via.

34. A method comprising:
fabricating non-orthogonal transistor fins on a substrate, the transistor fins being non-orthogonal relative to a plane of the substrate;
fabricating diffusion contacts with non-right angled sides over the fabricated non-orthogonal transistor fins, wherein the diffusion contacts are coupled to the non-orthogonal transistor fins;
depositing an etch stop material over the diffusion contacts;
depositing a dielectric layer over the etch stop material;
depositing a metallization hard mask layer over the dielectric layer; and
applying a first photoresist over the metallization hard mask layer, wherein the first photoresist is patterned with holes for forming first vias for coupling the at least one of the first vias to a memory element.

35. The method of claim 34 comprises applying a first anisotropic dry etch to transfer the photoresist pattern of the first photoresist into the dielectric layer and etch stop material such that holes are formed to a top surface of at least one of the diffusion contacts.

36. The method of claim 35 comprises:
removing the first photoresist;
applying a spacer film for forming the first vias after the first photoresist is removed;
applying a second anisotropic etch process to remove the spacer film from horizontal surfaces while leaving the spacer film on vertical surfaces;
depositing a first conductive metal after applying the second anisotropic etch process such that the deposited first conductive metal fills the first vias;
etching back the first conductive metal partially from the first vias;
depositing a cap layer over the etched back first conductive metal; and
polishing the cap layer such that the cap layer remains above the first vias.

37. The method of claim 36 comprises:
applying a third photoresist and patterning the third photoresist for forming source lines;
applying a third anisotropic etch process to form source line trenches, the third anisotropic etch process to etch partially through the dielectric layer; and
removing the third photoresist after applying the third anisotropic etch process.

38. The method of claim 37 comprises:
applying a fourth photoresist with a pattern for forming a second via; and
applying a fourth anisotropic etch process to transfer the fourth photoresist pattern through the dielectric layer and the etch stop material to just above at least one of the diffusion contacts.

39. The method of claim 38 comprises:
depositing a second conductive metal such that the second via and the source line trenches are filled with the second conductive metal; and
removing overburden of the second conductive metal such that the overburden is removed up to the cap layer and the metallization hard mask layer.

40. The method of claim 39 comprises:
etching the second conductive metal, in response to removing the overburden from the source line trenches such that the etching stops below a top surface of the dielectric layer;
depositing a source line passivation film in response to etching the second conductive metal; and
removing overburden of the source line passivation film and metallization hard mask layer such that the first via and the filled source line is exposed.

41. The method of claim 40 comprises:
forming a memory element such that one end of the memory element couples the at least one of the first vias; and
forming an interconnect and coupling the interconnect to the filled source line.

42. A system comprising:
a processor core;
a memory coupled to the processor core, the memory including:
non-orthogonal transistor fins which are non-orthogonal to transistor gates;
diffusion contacts with non-right angled sides, the diffusion contacts coupled to the non-orthogonal transistor fins;
first vias; and
at least one memory element coupled to at least one of the diffusion contacts through at least one of the first vias; and
a wireless interface for allowing the processor to communicate with another device.

43. The system of claim 42, wherein the memory element is a resistive memory element which is at least one of:
a magnetic tunneling junction;
a capacitor;
a phase change memory; or
a resistive random access memory (RRAM) material.

44. The system of claim 42, wherein the first via is a magnetic tunneling junction (MTJ) pillar via.
